(19) United States
(12) Patent Application Publication
(10) Pub. No.: US 2025/0282020 A1
(43) Pub. Date: Sep. 11, 2025

(54) POLISHING PAD AND METHOD FOR MANUFACTURING SEMICONDUCTOR DEVICE USING THE SAME

(71) Applicant: SK enpulse Co., Ltd., Gyeonggi-do (KR)

(72) Inventors: Jong Wook YOON, Seoul (KR); Jang Won SEO, Seoul (KR); Su Young MOON, Seoul (KR)

(21) Appl. No.: 19/072,828

(22) Filed: Mar. 6, 2025

(30) Foreign Application Priority Data
Mar. 6, 2024 (KR) 10-2024-0031964

(51) Int. Cl. B24B 37/24; B24B 53/017; H01L 21/306

(52) U.S. Cl. CPC B24B 37/24; B24B 53/017; H01L 21/30625

(57) ABSTRACT

A polishing pad and a method for manufacturing the same of the present disclosure maintain polishing performance required for a polishing process such as a polishing speed or a polishing profile, minimize defects that may occur on a wafer during a polishing process, and exhibit a property of color change when performing a polishing process using a slurry including an oxidizing agent. In addition, when using a polishing pad in a CMP process, a condition for selecting a polishing pad capable of distinguishing the use of polishing pad in a polishing process may be provided by identifying the degree of color change in the polishing pad under an acidic condition without a direct polishing test.

### CROSS-REFERENCE TO RELATED APPLICATION

The present application claims priority under 35 U.S.C. § 119(a) to Korean Patent Application Number 10-2024-0031964, filed on Mar. 6, 2024, in the Korean Intellectual Property Office, the entire disclosure of which is incorporated herein by reference.

### TECHNICAL FIELD

The present disclosure relates to a polishing pad used in a chemical mechanical planarization (CMP) process, and a method for manufacturing a semiconductor device using the same.

### BACKGROUND ART

Among semiconductor manufacturing processes, a chemical mechanical planarization (CMP) process is a process in which a wafer is attached to a head and, while bringing the wafer into contact with a surface of a polishing pad formed on a platen, a slurry is supplied thereto to chemically react the wafer surface, and the platen and the head are moved relative to each other to mechanically planarize an uneven portion of the wafer surface.

The chemical mechanical planarization process uses a polishing pad, and may be used in various ways not only in semiconductor manufacturing processes, but also in planarization processing of materials requiring high surface flatness such as memory disks, magnetic disks, optical materials such as optical lenses or reflective mirrors, glass plates and metals.

With miniaturization of semiconductor circuits, the importance of a CMP process is becoming more prominent. A polishing pad is one of essential raw materials in a CMP process of a semiconductor manufacturing process, and performs an important role in achieving CMP performance.

Various performances are required for the polishing pad, and the number of defects in the material after planarization processing is a factor that greatly affects the yield.

The polishing pad has its properties and physical properties changed depending on the combination and the composition of components such as a prepolymer, a curing agent and a foaming agent, and properties and physical properties of the manufactured polishing pad greatly affect performance in a CMP process.

In particular, when attempting to use a polishing pad in an actual polishing process, there have been inconveniences of having to consider properties such as yield through a direct polishing test.

Accordingly, in order to use a polishing pad in the field, a method capable of selecting a polishing pad without performing a direct polishing test needs to be developed.

### DISCLOSURE

### Technical Problem

The present disclosure is directed to providing a polishing pad and a method for manufacturing the same.

The present disclosure is also directed to providing a polishing pad capable of maintaining polishing performance required for a polishing process such as a polishing speed or a polishing profile, minimizing defects that may occur on a wafer during a polishing process, and exhibiting properties of change in color and change in surface zeta potential when performing a polishing process using a slurry including an oxidizing agent.

The present disclosure is also directed to providing a polishing pad capable of, due to the change in surface zeta potential, minimizing the occurrence of defects caused by a polishing process.

The present disclosure is also directed to providing, when using a polishing pad in a CMP process, a condition for selecting a polishing pad capable of distinguishing the use of polishing pad in a polishing process by identifying the degree of color change in the polishing pad under an acidic condition without a direct polishing test.

The present disclosure is also directed to providing a method for manufacturing a semiconductor device using the polishing pad.

### Technical Solution

In view of the above, a polishing pad according to one embodiment of the present disclosure includes a polishing layer, wherein the polishing layer is treated with 3% by weight of an aqueous H₂O₂ solution for 90 hours at 70° C., and the polishing layer treated with 3% by weight of the aqueous H₂O₂ solution may have a peak appearing at 1620 cm⁻¹ to 1650 cm⁻¹ when measuring an FT-IR (Fourier Transform Infrared Spectroscopy) spectrum.

A method for manufacturing a semiconductor device according to another embodiment of the present disclosure includes: providing a polishing pad including a polishing layer; and polishing a semiconductor substrate while conducting relative rotation so that a surface to be polished of the semiconductor substrate is in contact with a polishing surface of the polishing layer, wherein the polishing layer is treated with 3% by weight of an aqueous H₂O₂ solution for 90 hours at 70° C., and the polishing layer treated with 3% by weight of the aqueous H₂O₂ solution may have a peak appearing at 1620 cm⁻¹ to 1650 cm⁻¹ when measuring an FT-IR (Fourier Transform Infrared Spectroscopy) spectrum.

A polishing pad according to another embodiment of the present disclosure includes a polishing layer, wherein the polishing layer may have a surface zeta potential variance (Δ|Surface Zeta|Δ|Surface Zeta|) according to the following Equation 1, of 0.1 to 10:

$$Δ \vert Surface Zeta \vert = \frac{( - {Intercept}_{i} + Tracer )}{( - {Intercept}_{a} + Tracer )} \qquad [ Equation 1 ]$$

herein,
Interceptᵢ is zeta potential of the polishing layer untreated with 3% by weight of an aqueous H₂O₂ solution,
Interceptₐ is zeta potential of the polishing layer after being treated with 3% by weight of an aqueous H₂O₂ solution, and
Tracer is zeta potential of a silica slurry.

### Advantageous Effects

The present disclosure is capable of maintaining polishing performance required for a polishing process such as a polishing speed or a polishing profile, minimizing defects that may occur on a wafer during a polishing process, exhibiting properties of change in color and change in surface zeta potential when performing a polishing process using a slurry including an oxidizing agent, and, due to the change in surface zeta potential, minimizing the occurrence of defects caused by a polishing process.

The present disclosure is capable of providing a condition for selecting a polishing pad capable of distinguishing the use of polishing pad in a polishing process by identifying the degree of color change in the polishing pad under an acidic condition without a direct polishing test.

In addition, the present disclosure provides a method for manufacturing a semiconductor device using the polishing pad.

### BRIEF DESCRIPTION OF DRAWINGS

FIG. 1 shows a result of measuring an FT-IR spectrum before supplying a slurry for a polishing layer according to one embodiment of the present disclosure.

FIG. 2 shows a result of measuring an FT-IR spectrum after supplying a slurry for a polishing layer according to one embodiment of the present disclosure.

FIG. 3 shows a result of measuring an FT-IR spectrum after supplying a slurry for a polishing layer according to one embodiment of the present disclosure.

FIG. 4 shows a result of measuring an FT-IR spectrum after supplying a slurry for a polishing layer according to one embodiment of the present disclosure.

FIG. 5 shows a result of measuring an FT-IR spectrum after supplying a slurry for a polishing layer according to one embodiment of the present disclosure.

FIG. 6 shows an analysis result on a change in the area at a specific peak before and after supplying a slurry for a polishing layer according to one embodiment of the present disclosure.

FIG. 7 shows results of measuring physical properties for a polishing layer according to one embodiment of the present disclosure.

FIG. 8 shows SEM measurement images for a polishing layer according to one embodiment of the present disclosure.

FIG. 9 shows SEM measurement images for a polishing layer according to one embodiment of the present disclosure.

FIG. 10 shows SEM measurement images for a polishing layer according to one embodiment of the present disclosure.

FIG. 11 shows SEM measurement images for a polishing layer according to one embodiment of the present disclosure.

FIG. 12 is a schematic process diagram of a semiconductor device manufacturing process according to one embodiment of the present disclosure.

### BEST MODE

Hereinafter, embodiments of the present disclosure will be described in detail so that those skilled in the art may readily implement the present disclosure. However, the present disclosure may be embodied in various different forms, and is not limited to the embodiments described herein.

It needs to be understood that numbers expressing quantities of components, properties such as molecular weight, reaction conditions and the like used in the present disclosure are modified by a term “about” in all cases.

Unless otherwise stated in the present disclosure, all percentages, parts, ratios and the like are based on weight.

In the present disclosure, a description of “including” means that it may further include other components and does not exclude other components unless particularly stated on the contrary.

In the present disclosure, “a plurality of” refers to greater than one.

A polishing pad according to one embodiment of the present disclosure includes a polishing layer, wherein the polishing layer is treated with 3% by weight of an aqueous H₂O₂ solution for 90 hours at 70° C., and the polishing layer treated with 3% by weight of the aqueous H₂O₂ solution may have a peak appearing at 1620 cm⁻¹ to 1650 cm⁻¹ when measuring an FT-IR (Fourier Transform Infrared Spectroscopy) spectrum.

A polishing process using the polishing pad will be broadly described as follows.

In order to perform polishing by relatively perturbing the polishing pad and an object to be polished while pressing a surface to be polished of the object to be polished against the polishing pad, the polishing may be performed specifically by moving the object to be polished and at least one side of the polishing surface plate.

The polishing condition is not particularly limited, however, optimization may be achieved depending on an object to be polished. For example, the polishing may be performed under a condition in which the surface plate is rotated at a rotation speed of 200 rpm or less so that an object to be polished does not pop out, and the pressure applied to the object to be polished is set to a pressure level that does not cause damage after the polishing. In addition, the pressure condition may be maintained differently even when an object to be polished having a low-dielectric interlayer insulating film is used.

During the polishing, a slurry may be continuously supplied between the polishing pad and the surface to be polished using a pump and the like. The amount of slurry supplied is not limited, however, it is preferred that the surface of the polishing pad is always covered with a slurry.

A slurry used in a general polishing process may vary depending on materials to be polished and processes, and for example, may include 80% by weight to 100% by weight of a processing liquid that is a solution formed with an oxidizing agent such as hydrogen peroxide (H₂O₂) and ferric nitrate (Fe(NO₃)₃) and a dissolving agent, and 0% by weight to 20% by weight of abrasive particles such as silica (SiO₂), ceria (CeO₂) and alumina (Al₂O₃). In the polishing step of supplying the slurry, chemical polishing action by dissolution, embrittlement and the like using an oxidizing agent, a dissolving agent and the like included in the processing liquid, and physical polishing action by abrasive particles may occur simultaneously.

The slurry may include an oxidizing agent, and may include deionized water and a pH regulator such as ammonia, potassium hydroxide and sodium hydroxide.

The present disclosure relates to performing a polishing process by including an oxidizing agent in the slurry, and although the oxidizing agent included in the slurry is not particularly limited, an FT-IR spectrum for the polishing layer under a condition of using the slurry including H₂O₂ is measured for the purpose of specifying the disclosure.

The above-mentioned condition of pH 6 is obtained by including 3% by weight of H₂O₂ with respect to the total weight of the slurry, and may mean an acidic condition of pH 6 or lower. In other words, it may mean that 3% by weight of H₂O₂ is included as an oxidizing agent with respect to the total weight of the slurry, however, the condition is not limited to the above-mentioned example, and the content of H₂O₂ in the slurry may be adjusted to obtain an acidic condition of pH 6 or lower.

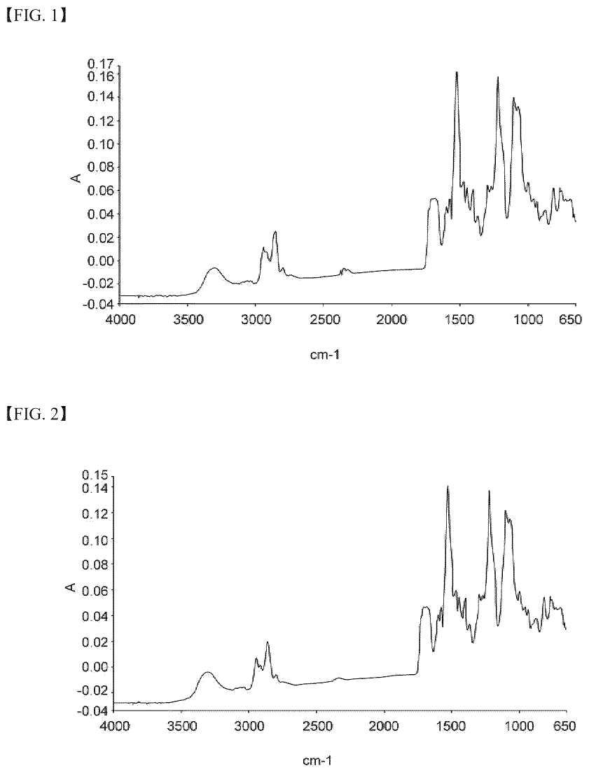

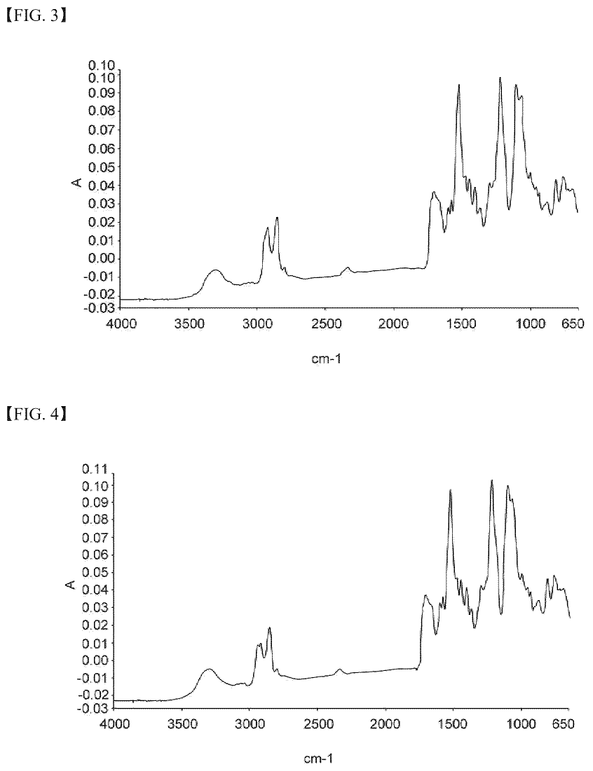

FIGS. 1 to 5 show results of measuring an FT-IR spectrum for the polishing layer of the present disclosure. Specifically, FIG. 1 relates to the polishing pad before treating with a slurry, and FIGS. 2 to 5 show results of measuring an FT-IR spectrum after treating with DIW or 3% by weight of H₂O₂.

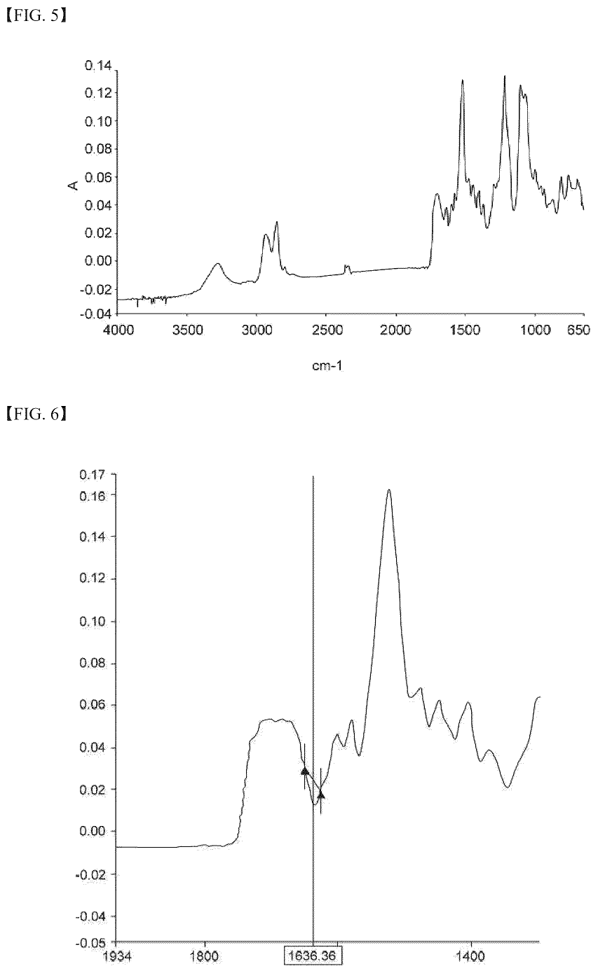

FIG. 1 shows a result of measuring an FT-IR spectrum for the polishing pad before treatment, and FIG. 5 shows a result of measuring an FT-IR spectrum for the polishing layer of the polishing pad after treating with 3% by weight of H₂O₂ for 90 hours at 70° C., and it is identified that there are changes in the peaks at 1600 cm⁻¹ to 1700 cm⁻¹, and particularly, there is a change in the peak at 1636 cm⁻¹.

Such changes in the measurement values of the FT-IR spectrum may be due to the structural change in the polyurethane in the polishing layer as shown in the following Reaction Formula 1.

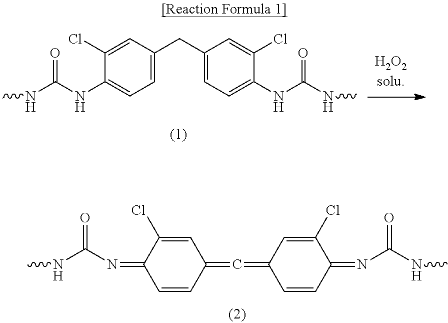

The compound (1) in Reaction Formula 1 includes a urea group, and may be an example of a compound in which a urea bond is formed by a reaction between a polyurethane prepolymer and a curing agent in the polishing layer.

The compound represented by (1) may undergo a structural change into a compound such as (2) as 3% by weight of H₂O₂ is supplied to the polishing layer. Specifically, the compound of (2) may be formed as the urea group structurally changes into a quinoid group.

As the urea group structurally changes into a quinoid group in the compound as described above, measurement values of the FT-IR spectrum may change.

In the polishing layer of the present disclosure, the changes in the FT-IR spectrum obtained by treatment with 3% by weight of H₂O₂ may also be identified through a change in color of the polishing layer.

The polishing layer changes to yellow in the color as it is treated with 3% by weight of H₂O₂, and specifically, may have a yellow index (YI) of 10 to 50, 20 to 40, and 30 to 40 when treated with 3% by weight of H₂O₂ for 30 hours to 90 hours. Having a yellow index in the above-mentioned range may mean that there are changes in the FT-IR spectrum by the treatment with 3% by weight of H₂O₂.

In addition, as to be described later, surface zeta potential of the polishing layer shows a negative value when a yellow index value as above is obtained by the treatment with 3% by weight of H₂O₂, and as the silica slurry also has negative zeta potential, the occurrence of defects may be prevented by repulsive force with a semiconductor wafer having negative zeta potential on the surface.

On the other hand, when the polishing layer is treated with deionized water instead of 3% by weight of H₂O₂, color change does not occur in the polishing layer even when time passes. Specifically, when measuring a yellow index (YI) after 30 hours, 60 hours and 90 hours while treating the polishing layer with deionized water, the yellow index is from 14 to 16, and it may be identified that there is no change compared to before the treatment with deionized water.

On the other hand, when the polishing layer of the polishing pad is treated with 3% by weight of H₂O₂, the yellow index (YI) may be from 10 to 35, 15 to 35, and 20 to 30 after 30 hours in a state of pH 6. In addition, the yellow index (YI) may be from 20 to 50, 25 to 40, and 30 to 40 after 60 hours. The yellow index (YI) may be from 20 to 50, 25 to 40, and 30 to 40 after 90 hours. In the above-mentioned range, surface zeta potential of the polishing layer shows a negative value, and as the silica slurry also has negative zeta potential, the occurrence of defects may be prevented by repulsive force with a semiconductor wafer having negative zeta potential on the surface.

When the polishing layer is treated with 3% by weight of H₂O₂ as described above, the urea group in Reaction Formula 1 is rearranged into a quinoid group, and as a result, the property of color change may be expressed by the chromophore of the quinoid group.

In addition to the property of color change, the polishing pad of the present disclosure may have surface zeta potential of −50 mV to −80 mV, −55 mV to −75 mV and −60 mV to −70 mV after being treated with 3% by weight of an aqueous H₂O₂ solution for 90 hours at 70° C. and introducing a silica slurry of −35 mV to −45 mV.

Zeta potential generally means physical properties that appear in particles in a suspension. There are two types of liquid layers present around particles. These are an inner region (stem layer: electron layer) where ions form a strong boundary and an outer region (defuse) where ions are relatively weakly bound. The outer region (defuse) is a region within a theoretical boundary where ions and particles are stably present. For example, when particles move, ions in the inner region move within a certain boundary. On the other hand, ions present outside the certain boundary move independently like a huge dispersing agent regardless of the particles. Potential at such a boundary is zeta potential. The silica slurry may have its own zeta potential in a suspension state in which silica particles are dispersed.

When the zeta potential is from −50 mV to −80 mV by being treated with a solution having a pH of 6 as described above, attachment of polishing chips on the polishing pad surface may be suppressed, thereby reducing the occurrence of scratches or defects on the surface of an object to be polished, and as a result, a product yield may be improved, and high planarization performance may be obtained.

Specifically, when the polishing layer is treated with 3% by weight of a H₂O₂ solution and maintains an acidic state with a pH of 6, the quinoid group in the compound represented by (2) in Reaction Formula 1 functions as a zwitterion, and a negative zeta potential value may be obtained.

When the zeta potential of the polishing layer exhibits a high negative charge under an acidic condition as described above, strong repulsive force is generated with a semiconductor wafer having negative zeta potential on the surface, and the occurrence of defects may be reduced in the polishing process.

When the polishing layer of the present disclosure is in an acidic condition with a pH of 6, that is, treated with 3% by weight of H₂O₂ as described above, the urethane group structurally changes into a quinoid group, and a peak at 1600 cm⁻¹ to 1700 cm⁻¹ appears when measuring an FT-IR (Fourier Transform Infrared Spectroscopy) spectrum, the property of color change, which is the yellow index (YI) of 10 to 35, is obtained when 30 hours pass, and the zeta potential is from −50 mV to −80 mV.

On the other hand, apart from the color change property and the zeta potential property obtained as above, physical properties of the polishing pad do not change.

Specifically, after 90 hours under a condition of treating the polishing layer with 3% by weight of H₂O₂, surface hardness for the polishing surface is from 55 shore D to 65 shore D at 25° C., elongation of the polishing layer is from 60% to 140%, and maximum stress of the polishing layer may be from 15 N/m² to 25 N/m². The surface hardness for the polishing surface, the elongation and the maximum stress of the polishing layer do not show any difference even when 90 hours pass after the treatment compared to before the treatment with the solution having a pH of 6.

In other words, it may be identified that, although there are no changes in the physical properties of the polishing layer under an acidic condition, there are changes in the color change property and the zeta potential property.

When identifying the color change property and the zeta potential change property in the polishing layer after the treatment with 3% by weight of H₂O₂ using such properties, polishing performance of the polishing layer and an effect of reducing the occurrence of defects in a wafer may be identified.

Specifically, in order to identify polishing performance and the effect of reducing wafer defects for a plurality of polishing pads, there has been inconvenience of having to identify polishing performance and the occurrence of defects through an actual polishing test in the art.

When using color change property and zeta potential change property under an acidic condition as in the present disclosure, it is possible to select a polishing pad through the color change property and the zeta potential change property in the polishing layer under a condition of being treated with 3% by weight of H₂O₂ even when exact information on the components of the polishing pad and each content thereof is not available.

Specifically, as for the zeta potential change property, the surface zeta potential variance (Δ|Surface Zeta|Δ|Surface Zeta|) according to the following Equation 1 may be from 0.1 to 10:

$$Δ \vert Surface Zeta \vert = \frac{( - {Intercept}_{i} + Tracer )}{( - {Intercept}_{a} + Tracer )} \qquad [ Equation 1 ]$$

herein,
Interceptᵢ is zeta potential of the polishing layer untreated with 3% by weight of an aqueous H₂O₂ solution,
Interceptₐ is zeta potential of the polishing layer after being treated with 3% by weight of an aqueous H₂O₂ solution, and
Tracer is zeta potential of a silica slurry.

The value of surface zeta potential change by Equation 1 may be from 0.1 to 10, 0.1 to 5, 0.1 to 3, 0.1 to 1, 0.1 to 0.9 and 0.1 to 0.7. By being treated with 3% by weight of an aqueous H₂O₂ solution in the above-mentioned range, a relatively large negative zeta potential value is obtained on the surface of the polishing layer, and the occurrence of defects may be prevented by strong repulsive force with a semiconductor wafer having negative zeta potential on the surface.

A plurality of pores are formed in the polishing layer in the polishing pad of the present disclosure, and the pores may have a diameter of 10 μm to 30 μm. By using a polishing layer having a plurality of pores formed therein as described above, polishing efficiency of the polishing pad may be improved.

The polishing layer in the polishing pad may be prepared by curing a composition including a urethane-based prepolymer, a curing agent and a foaming agent, and then molding the result.

In one embodiment, the polishing layer may include a polishing layer including a cured material formed from a composition including a urethane-based prepolymer, a curing agent and a foaming agent.

Each component included in the composition will be specifically described below.

The ‘prepolymer’ means a polymer having a relatively low molecular weight obtained by stopping a degree of polymerization in the middle so as to facilitate molding in preparing a cured material. The prepolymer may be molded to a final cured material either by itself or after reacting with other polymerizable compounds.

In one embodiment, the urethane-based prepolymer may be prepared by reacting an isocyanate compound and a polyol.

As the isocyanate compound used for preparing the urethane-based prepolymer, one selected from the group consisting of aromatic diisocyanates, aliphatic diisocyanates, alicyclic diisocyanates and combinations thereof may be used.

The isocyanate compound may include one selected from the group consisting of, for example, 2,4-toluenediisocyanate (2,4-TDI), 2,6-toluenediisocyanate (2,6-TDI) naphthalene-1,5-diisocyanate, para-phenylenediisocyanate, tolidinediisocyanate, 4,4′-diphenylmethanediisocyanate, hexamethylenediisocyanate, dicyclohexylmethanediisocyanate, isophorone diisocyanate and combinations thereof.

The ‘polyol’ means a compound including at least two hydroxyl groups (—OH) per molecule. The polyol may include one selected from the group consisting of, for example, polyether-based polyols, polyester-based polyols, polycarbonate-based polyols, acryl-based polyols and combinations thereof.

The polyol may include one selected from the group consisting of, for example, polytetramethylene ether glycol, polypropylene ether glycol, ethylene glycol, 1,2-propylene glycol, 1,3-propylene glycol, 1,2-butanediol, 1,3-butanediol, 2-methyl-1,3-propanediol, 1,4-butanediol, neopentyl glycol, 1,5-pentanediol, 3-methyl-1,5-pentanediol, 1,6-hexanediol, diethylene glycol, dipropylene glycol, tripropylene glycol and combinations thereof.

The polyol may have a weight average molecular weight (Mw) of about 100 g/mol to about 3,000 g/mol. The polyol may have a weight average molecular weight (Mw) of, for example, about 100 g/mol to about 3,000 g/mol, for example, about 100 g/mol to about 2,000 g/mol, and for example, about 100 g/mol to about 1,800 g/mol.

In one embodiment, the polyol may include a low molecular weight polyol having a weight average molecular weight (Mw) of about 100 g/mol or greater and less than about 300 g/mol, and a high molecular weight polyol having a weight average molecular weight (Mw) of about 300 g/mol or greater and about 1800 g/mol or less.

The urethane-based prepolymer may have a weight average molecular weight (Mw) of about 500 g/mol to about 3,000 g/mol. The urethane-based prepolymer may have a weight average molecular weight (Mw) of, for example, about 600 g/mol to about 2,000 g/mol, and for example, about 800 g/mol to about 1,000 g/mol.

In one embodiment, the isocyanate compound for preparing the urethane-based prepolymer may include an aromatic diisocyanate compound, and the aromatic diisocyanate compound may include, for example, 2,4-toluenediisocyanate (2,4-TDI) and 2,6-toluenediisocyanate (2,6-TDI). The polyol compound for preparing the urethane-based prepolymer may include polytetramethylene ether glycol (PTMEG) and diethylene glycol (DEG).

In another embodiment, the isocyanate compound for preparing the urethane-based prepolymer may include an aromatic diisocyanate compound and an alicyclic diisocyanate compound. For example, the aromatic diisocyanate compound may include 2,4-toluenediisocyanate (2,4-TDI) and 2,6-toluenediisocyanate (2,6-TDI) and the alicyclic diisocyanate compound may include dicyclohexylmethane diisocyanate (H₁₂MDI). The polyol compound for preparing the urethane-based prepolymer may include polytetramethylene ether glycol (PTMEG) and diethylene glycol (DEG).

The urethane-based prepolymer may have an isocyanate end group content (NCO %) of about 5% by weight to about 11% by weight, for example, about 5% by weight to about 10% by weight, for example, about 5% by weight to about 8% by weight, and for example, about 8% by weight to about 10% by weight.

The isocyanate end group content (NCO %) of the urethane-based prepolymer may be designed by comprehensively controlling type and content of the isocyanate compound and the polyol compound for preparing the urethane-based prepolymer, process conditions such as temperature, pressure and time of the process for preparing the urethane-based prepolymer, type and content of additives used for preparing the urethane-based prepolymer, and the like.

The curing agent is a compound for forming a final cured structure in the polishing layer by chemically reacting with the urethane-based prepolymer, and may include, for example, an amine compound or an alcohol compound. Specifically, the curing agent may include one selected from the group consisting of aromatic amines, aliphatic amines, aromatic alcohols, aliphatic alcohols and combinations thereof.

For example, the curing agent may include one selected from the group consisting of 4,4′-methylenebis(2-chloroaniline) (MOCA), diethyltoluenediamine (DETDA), diaminodiphenylmethane, dimethyl thio-toluene diamine (DMTDA), propanediol bis p-aminobenzoate, methylene bis-methylanthranilate, diaminodiphenylsulfone, m-xylylenediamine, isophoronediamine, ethylenediamine, diethylenetriamine, triethylenetetramine, polypropylenediamine, polypropylenetriamine, bis(4-amino-3-chlorophenyl)methane and combinations thereof.

A content of the curing agent may be from about 18 parts by weight to about 27 parts by weight, for example, from about 19 parts by weight to about 26 parts by weight, and for example, from about 20 parts by weight to about 26 parts by weight based on 100 parts by weight of the urethane-based prepolymer. The curing agent content satisfying the above-mentioned range may be more advantageous in obtaining target performance of the polishing pad.

The foaming agent is a component for forming a pore structure in the polishing layer, and may include one selected from the group consisting of a solid-state foaming agent, a gas-state foaming agent, a liquid-state foaming agent and combinations thereof. In one embodiment, the foaming agent may include a solid-state foaming agent, a gas-state foaming agent or a combination thereof.

The solid-state foaming agent may have an average particle diameter of about 5 μm to about 200 μm, for example, about 20 μm to about 50 μm, for example, about 21 μm to about 50 μm, and for example, about 25 μm to about 45 μm. When the solid-state foaming agent is thermally expanded particles to describe later, the average particle diameter of the solid-state foaming agent may mean an average particle diameter of the thermally expanded particles themselves, and when the solid-state foaming agent is unexpanded particles to describe later, the average particle diameter of the solid-state foaming agent may mean an average particle diameter of particles after being expanded by heat or pressure.

The solid-state foaming agent may include expandable particles. The expandable particles are particles having a property of being expandable by heat, pressure or the like, and final sizes in the polishing layer may be determined by heat, pressure or the like applied during the process for preparing the polishing layer. The expandable particles may include thermally expanded particles, unexpanded particles or a combination thereof. The thermally expanded particles are particles that are pre-expanded by heat, and mean particles having little or no changes in the size by heat or pressure applied during the process for preparing the polishing layer. The unexpanded particles are particles that are not pre-expanded, and mean particles having the final size determined after being expanded by heat or pressure applied during the process for preparing the polishing layer.

The expandable particles may include: an outer cover made of a resin material; and an expansion-inducing component present on the inside sealed by the outer cover.

For example, the outer cover may include a thermoplastic resin, and the thermoplastic resin may be one or more types selected from the group consisting of vinylidene chloride-based copolymers, acrylonitrile-based copolymers, methacrylonitrile-based copolymers and acryl-based copolymers.

The expansion-inducing component may include one selected from the group consisting of hydrocarbon compounds, chlorofluoro compounds, tetraalkylsilane compounds and combinations thereof.

Specifically, the hydrocarbon compound may include one selected from the group consisting of ethane, ethylene, propane, propene, n-butane, isobutane, n-butene, isobutene, n-pentane, isopentane, neopentane, n-hexane, heptane, petroleum ether and combinations thereof.

The chlorofluoro compound may include one selected from the group consisting of trichlorofluoromethane (CCl₃F), dichlorodifluoromethane (CCl₂F₂), chlorotrifluoromethane (CClF₃), tetrafluoroethylene (CClF₂—CClF₂) and combinations thereof.

The tetraalkylsilane compound may include one selected from the group consisting of tetramethylsilane, trimethylethylsilane, trimethylisopropylsilane, trimethyl-n-propylsilane and combinations thereof.

The solid-state foaming agent may optionally include inorganic component-treated particles. For example, the solid-state foaming agent may include inorganic component-treated expandable particles. In one embodiment, the solid-state foaming agent may include silica (SiO₂) particle-treated expandable particles. Treating the solid-state foaming agent with an inorganic component may prevent aggregation between the plurality of particles. The inorganic component-treated solid-state foaming agent may have different chemical, electrical and/or physical properties of the foaming agent surface from the solid-state foaming agent not treated with an inorganic component.

The solid-state foaming agent may be included in a content of about 0.5 parts by weight to about 10 parts by weight, for example, about 1 part by weight to about 3 parts by weight, for example, about 1.3 parts by weight to about 2.7 parts by weight, and for example, about 1.3 parts by weight to about 2.6 parts by weight based on 100 parts by weight of the urethane-based prepolymer.

Type and content of the solid-state foaming agent may be designed depending on target pore structure and properties of the polishing layer.

The gas-state foaming agent may include an inert gas. The gas-state foaming agent may be introduced during the reaction between the urethane-based prepolymer and the curing agent, and used as a pore-forming element.

The inert gas is not particularly limited in the type as long as it is a gas that does not participate in the reaction between the urethane-based prepolymer and the curing agent. For example, the inert gas may include one selected from the group consisting of nitrogen gas (N₂), argon gas (Ar), helium gas (He) and combinations thereof. Specifically, the inert gas may include nitrogen gas (N₂) or argon gas (Ar).

Type and content of the gas-state foaming agent may be designed depending on target pore structure and properties of the polishing layer.

In one embodiment, the foaming agent may include a solid-state foaming agent. For example, the foaming agent may be formed only with a solid-state foaming agent.

The solid-state foaming agent includes expandable particles, and the expandable particles may include thermally expanded particles. For example, the solid-state foaming agent may be formed only with thermally expanded particles. When the solid-state foaming agent is formed only with thermally expanded particles without including the unexpanded particles, variability of the pore structure is reduced, however, predictability increases, which is advantageous in obtaining uniform pore properties over the entire area of the polishing layer.

In one embodiment, the thermally expanded particles may be particles having an average particle diameter of about 5 μm to about 200 μm. The thermally expanded particles may have an average particle diameter of about 5 μm to about 100 μm, for example, about 10 μm to about 80 μm, for example, about 20 μm to about 70 μm, for example, about 20 μm to about 50 μm, for example, about 30 μm to about 70 μm, for example, about 25 μm to 45 μm, for example, about 40 μm to about 70 μm, and for example, about 40 μm to about 60 μm. The average particle diameter may be defined as D50 of the thermally expanded particles.

In one embodiment, the thermally expanded particles may have density of about 30 kg/m³ to about 80 kg/m³, for example, about 35 kg/m³ to about 80 kg/m³, for example, about 35 kg/m³ to about 75 kg/m³, for example, about 38 kg/m³ to about 72 kg/m³, for example, about 40 kg/m³ to about 75 kg/m³, and for example, about 40 kg/m³ to about 72 kg/m³.

In one embodiment, the foaming agent may include a gas-state foaming agent. For example, the foaming agent may include a solid-state foaming agent and a gas-state foaming agent. Descriptions on the solid-state foaming agent are the same as the descriptions provided above.

The gas-state foaming agent may include nitrogen gas.

The gas-state foaming agent may be injected through a predetermined injection line during the process of mixing the urethane-based prepolymer, the solid-state foaming agent and the curing agent. The gas-state foaming agent may be injected at an injection rate of about 0.8 L/min to about 2.0 L/min, for example, about 0.8 L/min to about 1.8 L/min, for example, about 0.8 L/min to about 1.7 L/min, for example, about 1.0 L/min to about 2.0 L/min, for example, about 1.0 L/min to about 1.8 L/min, and for example, about 1.0 L/min to about 1.7 L/min.

The composition for preparing the polishing layer may further include other additives such as a surfactant and a reaction rate control agent. The names such as ‘surfactant’ and ‘reaction rate control agent’ are arbitrary names based on the main role of the corresponding materials, and each of the corresponding materials does not necessarily perform only the function limited to the role indicated by the corresponding name.

The surfactant is not particularly limited as long as it is a material performing a role of preventing a phenomenon such as aggregation or overlapping of pores. For example, the surfactant may include a silicone-based surfactant.

The surfactant may be used in a content of about 0.2 parts by weight to about 2 parts by weight based on 100 parts by weight of the urethane-based prepolymer. Specifically, the surfactant may be included in a content of about 0.2 parts by weight to about 1.9 parts by weight, for example, about 0.2 parts by weight to about 1.8 parts by weight, for example, about 0.2 parts by weight to about 1.7 parts by weight, for example, about 0.2 parts by weight to about 1.6 parts by weight, for example, about 0.2 parts by weight to about 1.5 parts by weight, and for example, about 0.5 parts by weight to 1.5 parts by weight based on 100 parts by weight of the urethane-based prepolymer. When including the surfactant in a content within the above-mentioned range, pores derived from the gas-state foaming agent may be stably formed and maintained in the mold.

The reaction rate control agent performs a role of accelerating or delaying the reaction, and depending on the purpose, a reaction accelerator, a reaction retarder or both may be used. The reaction rate control agent may include a reaction accelerator. For example, the reaction accelerator may be one or more types of reaction accelerators selected from the group consisting of tertiary amine-based compounds and organometal-based compounds.

Specifically, the reaction rate control agent may include one or more types selected from the group consisting of triethylenediamine, dimethylethanolamine, tetramethylbutanediamine, 2-methyl-triethylenediamine, dimethylcyclohexylamine, triethylamine, triisopropanolamine, 1,4-diazabicyclo(2,2,2)octane, bis(2-methylaminoethyl)ether, trimethylaminoethylethanolamine, N,N,N,N,N″-pentamethyldiethylenetriamine, dimethylaminoethylamine, dimethylaminopropylamine, benzyldimethylamine, N-ethylmorpholine, N,N-dimethylaminoethylmorpholine, N,N-dimethylcyclohexylamine, 2-methyl-2-azanorbornane, dibutyl tin dilaurate, stannous octoate, dibutyl tin diacetate, dioctyl tin diacetate, dibutyl tin maleate, dibutyl tin di-2-ethylhexanoate and dibutyl tin dimercaptide. Specifically, the reaction rate control agent may include one or more types selected from the group consisting of benzyldimethylamine, N,N-dimethylcyclohexylamine and triethylamine.

The reaction rate control agent may be used in an amount of about 0.05 parts by weight to about 2 parts by weight based on 100 parts by weight of the urethane-based prepolymer. Specifically, the reaction rate control agent may be used in an amount of about 0.05 parts by weight to about 1.8 parts by weight, for example, about 0.05 parts by weight to about 1.7 parts by weight, for example, about 0.05 parts by weight to about 1.6 parts by weight, for example, about 0.1 parts by weight to about 1.5 parts by weight, for example, about 0.1 parts by weight to about 0.3 parts by weight, for example, about 0.2 parts by weight to about 1.8 parts by weight, for example, about 0.2 parts by weight to about 1.7 parts by weight, for example, about 0.2 parts by weight to about 1.6 parts by weight, for example, about 0.2 parts by weight to about 1.5 parts by weight, and for example, about 0.5 parts by weight to about 1 part by weight based on 100 parts by weight of the urethane-based prepolymer. When the reaction rate control agent is used in the content range described above, a polishing layer having desired pore size and hardness may be formed by properly controlling the curing reaction rate of the prepolymer composition.

When the polishing pad includes a cushion layer, the cushion layer performs a role of absorbing and dispersing an external impact applied to the polishing layer while supporting the polishing layer, thereby minimizing the occurrence of damages and defects for a subject to be polished during the polishing process using the polishing pad.

The cushion layer may include a non-woven fabric or suede, but is not limited thereto.

In one embodiment, the cushion layer may be a resin-impregnated non-woven fabric. The non-woven fabric may be a fibrous non-woven fabric including one selected from the group consisting of polyester fibers, polyamide fibers, polypropylene fibers, polyethylene fibers and combinations thereof.

The resin impregnated into the non-woven fabric may include one selected from the group consisting of a polyurethane resin, a polybutadiene resin, a styrene-butadiene copolymer resin, a styrene-butadiene-styrene copolymer resin, an acrylonitrile-butadiene copolymer resin, a styrene-ethylene-butadiene-styrene copolymer resin, a silicone rubber resin, a polyester-based elastomer resin, a polyamide-based elastomer resin and combinations thereof.

Hereinafter, a method for manufacturing the polishing pad will be described in detail.

Another embodiment according to the present disclosure may provide a method for manufacturing a polishing pad, the method including: preparing a prepolymer composition; preparing a composition for preparing a polishing layer including the prepolymer composition, a foaming agent and a curing agent; and preparing a polishing layer by curing the composition for preparing a polishing layer.

The preparing of a prepolymer composition may be a process of preparing a urethane-based prepolymer by reacting a diisocyanate compound and a polyol compound. Descriptions on the diisocyanate compound and the polyol compound are the same as the descriptions provided above regarding the polishing pad.

The isocyanate group (NCO group) of the prepolymer composition may be included in a content of about 5% by weight to about 15% by weight, for example, about 5% by weight to about 8% by weight, for example, about 5% by weight to about 7% by weight, for example, about 8% by weight to about 15% by weight, for example, about 8% by weight to about 14% by weight, for example, about 8% by weight to about 12% by weight, and for example, about 8% by weight to about 10% by weight.

The isocyanate group content in the prepolymer composition may be derived from the isocyanate end group of the urethane-based prepolymer, an unreacted isocyanate group of the diisocyanate compound, or the like.

The prepolymer composition may have viscosity of about 100 cps to about 1,000 cps, for example, about 200 cps to about 800 cps, for example, about 200 cps to about 600 cps, for example, about 200 cps to about 550 cps, and for example, about 300 cps to about 500 cps at about 80° C.

The foaming agent may include a solid-state foaming agent or a gas-state foaming agent.

When the foaming agent includes a solid-state foaming agent, the preparing of a composition for preparing a polishing layer may include: preparing a first preliminary composition by mixing the prepolymer composition and the solid-state foaming agent; and preparing a second preliminary composition by mixing the first preliminary composition and a curing agent.

The first preliminary composition may have viscosity of about 1,000 cps to about 2,000 cps, for example, about 1,000 cps to about 1,800 cps, for example, about 1,000 cps to about 1,600 cps, and for example, about 1,000 cps to about 1,500 cps at about 80° C.

When the foaming agent includes a gas-state foaming agent, the preparing of a composition for preparing a polishing layer may include: preparing a third preliminary composition including the prepolymer composition and the curing agent; and preparing a fourth preliminary composition by injecting the gas-state foaming agent into the third preliminary composition.

In one embodiment, the third preliminary composition may further include a solid-state foaming agent.

In one embodiment, the process for preparing a polishing layer may include: preparing a mold preheated to a first temperature; injecting the composition for preparing a polishing layer into the preheated mold for curing; and post-curing the cured composition for preparing a polishing layer under a second temperature condition higher than the preheating temperature.

In one embodiment, the first temperature may be from about 60° C. to about 100° C., for example, from about 65° C. to about 95° C., and for example, from about 70° C. to about 90° C.

In one embodiment, the second temperature may be from about 100° C. to about 130° C., for example, from about 100° C. to 125° C., and for example, from about 100° C. to about 120° C.

The curing of the composition for preparing a polishing layer at the first temperature may be conducted for about 5 minutes to about 60 minutes, for example, for about 5 minutes to about 40 minutes, for example, for about 5 minutes to about 30 minutes, and for example, for about 5 minutes to about 25 minutes.

The post-curing of the composition for preparing a polishing layer, which is cured at the first temperature, at the second temperature may be conducted for about 5 hours to about 30 hours, for example, for about 5 hours to about 25 hours, for example, for about 10 hours to about 30 hours, for example, for about 10 hours to about 25 hours, for example, for about 12 hours to about 24 hours, and for example, for about 15 hours to about 24 hours.

The method for manufacturing the polishing pad may include processing at least one surface of the polishing layer. The processing may be forming a groove.

As another example, the processing of at least one surface of the polishing layer may include at least one of forming a groove on at least one surface of the polishing layer (1); line turning at least one surface of the polishing layer (2); and roughening at least one surface of the polishing layer (3).

In the step (1), the groove may include at least one of a concentric circular groove formed spaced apart from the center of the polishing layer at a predetermined interval; and a radial groove continuously connected from the center of the polishing layer to the edge of the polishing layer.

In the step (2), the line turning may be conducted using a method of cutting the polishing layer by a predetermined thickness using a cutting tool.

In the step (3), the roughening may be conducted using a method of processing the surface of the polishing layer using a sanding roller.

The method for manufacturing the polishing pad may further include laminating a cushion layer on the other surface of the polishing surface of the polishing layer.

The polishing layer and the cushion layer may be laminated through a heat melt adhesive.

The heat melt adhesive is coated on the other surface of the polishing surface of the polishing layer and the heat melt adhesive is coated on the surface to be in contact with the polishing layer of the cushion layer, and, after laminating the polishing layer and the cushion layer so that the surfaces each coated with the heat melt adhesive are in contact with each other, the two layers may be fused using a pressure roller.

In another embodiment, the method includes: providing a polishing pad including a polishing layer; and polishing a subject to be polished while conducting relative rotation so that a surface to be polished of the subject to be polished is in contact with a polishing surface of the polishing layer.

FIG. 8 illustrates a schematic process diagram of the process for manufacturing a semiconductor device according to one embodiment. Referring to FIG. 8, the polishing pad 110 according to one embodiment is installed on a surface plate 120, and then a semiconductor substrate 130, a subject to be polished, is disposed on the polishing pad 110. Herein, the surface to be polished of the semiconductor substrate 130 is in direct contact with a polishing surface of the polishing pad 110. For the polishing, a polishing slurry 150 may be sprayed onto the polishing pad through a nozzle 140. A flow rate of the polishing slurry 150 supplied through the nozzle 140 may be selected depending on the purpose within a range of about 10 cm³/minute to about 1,000 cm³/minute, and for example, about 50 cm³/minute to about 500 cm³/minute, however, the flow rate is not limited thereto.

After that, the semiconductor substrate 130 and the polishing pad 110 may rotate relative to each other to polish the surface of the semiconductor substrate 130. Herein, the rotation direction of the semiconductor substrate 130 and the rotation direction of the polishing pad 110 may be the same direction or may be the opposite directions. The rotation speeds of the semiconductor substrate 130 and the polishing pad 110 may each be selected depending on the purpose in a range of about 10 rpm to about 500 rpm, and for example, about 30 rpm to about 200 rpm, however, the rotation speeds are not limited thereto.

The semiconductor substrate 130 may be pressurized with a predetermined load to be brought into contact with the polishing surface of the polishing pad 110 while being installed on a polishing head 160 to have its surface polished. The load applied to the surface of the semiconductor substrate 130 and the polishing surface of the polishing pad 110 by the polishing head 160 may be selected depending on the purpose in a range of about 1 gf/cm² to about 1,000 gf/cm², and for example, about 10 gf/cm² to about 800 gf/cm², however, the load is not limited thereto.

In one embodiment, the method for manufacturing a semiconductor device may further include, in order to maintain the polishing surface of the polishing pad 110 in a state suitable for polishing, processing the polishing surface of the polishing pad 110 through a conditioner 170 simultaneously with the polishing of the semiconductor substrate 130.

Hereinafter, specific examples of the present disclosure will be provided. However, the examples described below are only to specifically illustrate or describe the present disclosure, and the present disclosure is not limited thereto.

### Example 1

### Manufacture of Polishing Pad

Diisocyanate and polyol were mixed in a composition ratio of the following Table 1 and introduced to a 4-neck flask. Then, the mixture was reacted at 80° C. to prepare a preliminary composition including a urethane-based prepolymer. The content of the isocyanate group (NCO group) in the preliminary composition was adjusted to 9% by weight. 4,4′-methylenebis(2-chloroaniline) (MOCA) was mixed with the preliminary composition as a curing agent, so that the molar ratio of the NH₂ group in the MOCA was 0.96 with respect to the NCO group in the preliminary composition. In addition, 1.0 part by weight of a solid-state foaming agent (Akzonobel), an expandable particle, was mixed with the preliminary composition. The preliminary composition was injected into a mold having a width of 1,000 mm, a length of 1,000 mm and a height of 3 mm and preheated to 90° C. at a discharge rate of 10 kg/min, and, while the preliminary composition in which the curing agent and the solid-state foaming agent were mixed was injected, nitrogen (N₂) gas was simultaneously injected thereinto as a gas-state foaming agent at an injection rate of 1.0 L/min. Subsequently, the preliminary composition was subjected to a post-curing reaction under a temperature condition of 110° C. to prepare a polishing layer. After that, the surface of the prepared polishing layer was ground using a grinding machine, and after going through a process of grooving using a tip, a porous polyurethane sheet having a size of an average thickness of 2 mm and an average diameter of 76.2 cm was prepared.

On one surface of a support layer having a structure in which a non-woven fabric including a polyester resin fiber is impregnated with a urethane-based resin and having a thickness of 1.4 mm, a double-sided adhesive tape was attached, and the polyurethane sheet and the support layer were laminated to manufacture a polishing pad.

### Example 2

A polishing pad was manufactured in the same manner as in Example 1, except that the molar ratio of the NH₂ group in the MOCA was 0.8 with respect to the NCO group in the preliminary composition.

### Comparative Example 1

A prepolymer was prepared in the same manner as in Example 1, and after mixing 3 parts by weight of a solid-state foaming agent in advance with respect to 100 parts by weight of the urethane-based prepolymer, the mixture was injected into a prepolymer tank.

The urethane-based prepolymer and ethylene glycol used as a curing agent were used through each input line and stirred while introducing a tin salt catalyst (T-9 product manufactured by Air Products) used as a reaction catalyst into a mixing head at a constant rate. Herein, the molar equivalent of the NCO group of the urethane-based prepolymer and the molar equivalent of the reactive group of the curing agent were adjusted to 1:1, and the total amount of input was maintained at a speed of 10 kg/minute.

The stirred raw material was injected into a mold preheated to 90° C., and prepared into a single porous polyurethane sheet. After that, the surface of the prepared porous polyurethane sheet was ground using a grinding machine, and after going through a process of grooving using a tip, the porous polyurethane sheet was prepared to have a size of an average thickness of 2 mm and an average diameter of 76.2 cm.

The polyurethane sheet and suede (base layer, average thickness: 1.1 mm) were thermosetted at 120° C. using a hot melt film (manufacturer: SKC, product name: TF-00) to manufacture a polishing pad. The remaining processes were performed in the same manner as in Example 1.

### Comparative Example 2

A polishing pad was manufactured in the same manner as in Comparative Example 1, except that the diisocyanate and the polyol were mixed in a different composition ratio of the following Table 1.

The composition of the preliminarily composition, the curing agent and the process condition for each of Example 1, Example 2, Comparative Example 1 and Comparative Example 2 are shown in the following Table 1.

TABLE 1

| | | | | | Comparative | | Comparative |
|---|---|---|---|---|---|---|---|
| Item | | Example 1 | Example 2 | | Example 1 | | Example 2 |
| Composition | Diisocyanate | 2,4-TDI | | 73 | 79 | 79 | — |
| of | | 2,6-TDI | | 17 | 17 | 17 | — |
| Preliminary | | IPDI | | — | — | — | 90.2 |
| Composition | | H₁₂MDI | | 10 | 10 | 10 | 9.8 |
| | | Total (% by weight) | | 100 | 100 | 100 | 100 |
| | Polyol | PTMG (Mw 1000) | | 90.8 | 90.8 | 90.8 | 36.1 |
| | | DEG (Mw 106) | | 9.2 | 9.2 | 9.2 | 63.9 |
| | | Total (% by weight) | | 100 | 100 | 100 | 100 |
| | Preliminary Composition | | | 9 | 9 | 9 | 9 |
| | NCO Group Content (% | | | | | | |
| | by weight) | | | | | | |
| Amine | Molar Ratio of NH₂ of | | | 0.96 | 0.8 | — | — |
| Curing | Curing Agent with | | | | | | |
| Agent | respect to NCO in | | | | | | |
| | Preliminary Composition | | | | | | |
| Ethylene | Molar Ratio of Reactive | | | — | — | 1 | 1.3 |
| Glycol | Group of Curing Agent | | | | | | |
| | with respect to NCO in | | | | | | |
| | Preliminary Composition | | | | | | |
| Process | Prepolymer Preparation | | | 80 | 80 | 80 | 80 |
| Condition | Reaction Temperature | | | | | | |
| | (° C.) | | | | | | |
| | Curing Mold Preheating | | | 90 | 90 | 90 | 90 |
| | Temperature (° C.) | | | | | | |
| | Post-Curing Temperature | | | 110 | 110 | 110 | 110 |
| | (° C.) | | | | | | |

### Experimental Example 1

The porous polyurethane sheet prepared in Example 1 was prepared to have a thickness of 1 mm without forming a groove, and a color change thereof was identified.

In order to identify the color change, deionized water (DIW) and 3% by weight of a H₂O₂ solution were supplied, and after maintaining the temperature condition differently at 25° C. to 70° C., analyses on the occurrences of color change and hardness change during 0 hour to 90 hours were performed.

The color change was measured using Hunterlab Ultrascan Pro, and, based on the radius of the polishing layer, the color change of the center, the middle and the edge portions was measured, and the result was digitized as a Yellow Index (YI).

In addition, prior to the above-mentioned experiment, an FT-IR (Fourier Transform Infrared Spectroscopy) spectrum was measured for the porous polyurethane sheet prepared in Example 1. 3% by weight of a H₂O₂ solution was supplied, and after maintaining the temperature condition differently at 25° C. to 70° C., an FT-IR (Fourier Transform Infrared Spectroscopy) spectrum after 90 hours was measured.

The experimental results are shown in FIGS. 1 to 5 and the following Table 2.

TABLE 2

| | Solution | Temperature | | 0 hr | 30 hr | 60 hr | 90 hr |
|---|---|---|---|---|---|---|---|
| Example 1 | DIW | 25° C. | YI | 14.8 | 14.7 | 14.8 | 14.6 |
| | | | Hardness | 56.2 | 57.1 | 56.8 | 56.3 |
| | | 50° C. | YI | — | 15.1 | 14.1 | 14.5 |
| | | | Hardness | | 56.0 | 55.9 | 57.1 |
| | | 70° C. | YI | 14.8 | 14.3 | 15.1 | 14.7 |
| | | | Hardness | 56.2 | 56.7 | 55.9 | 56.2 |
| | 3% by weight of | 25° C. | YI | 14.8 | 19.6 | 20.1 | 15.5 |
| | H₂O₂ Solution | | Hardness | 56.2 | 55.9 | 56.1 | 55.5 |
| | | 50° C. | YI | — | 26.5 | 27.7 | 33.8 |
| | | | Hardness | | 55.8 | 56.2 | 55.5 |
| | | 70° C. | YI | 14.8 | 28.7 | 33.8 | 33.8 |
| | | | Hardness | 56.2 | 56.1 | 56.4 | 55.7 |
| Example 2 | DIW | 25° C. | YI | 14.9 | 14.7 | 14.5 | 14.7 |
| | | | Hardness | 56.2 | 55.8 | 56.2 | 55.7 |
| | | 50° C. | YI | 14.9 | 14.9 | 14.3 | 14.7 |
| | | | Hardness | 56.2 | 55.0 | 55.2 | 55.1 |
| | | 70° C. | YI | 14.9 | 14.6 | 15.0 | 14.8 |
| | | | Hardness | 56.2 | 54.8 | 55.0 | 54.6 |
| | 3% by weight of | 25° C. | YI | 14.9 | 18.2 | 19.7 | 20.3 |
| | H₂O₂ Solution | | Hardness | 56.2 | 55.7 | 56.4 | 55.9 |
| | | 50° C. | YI | 14.9 | 22.5 | 23.7 | 28.8 |
| | | | Hardness | 56.2 | 55.3 | 55.1 | 55.3 |
| | | 70° C. | YI | 14.9 | 26.4 | 29.3 | 30.2 |
| | | | Hardness | 56.2 | 54.6 | 55.1 | 54.7 |
| Comparative | DIW | 25° C. | YI | 10.5 | 10.8 | 10.8 | 10.9 |
| Example 1 | | | Hardness | 30.2 | 30.5 | 30.8 | 30.5 |
| | | 70° C. | YI | 10.5 | 10.2 | 10.9 | 10.8 |
| | | | Hardness | 30.2 | 30.6 | 30.0 | 30.7 |
| | 3% by weight of | 25° C. | YI | 10.5 | 10.9 | 11.4 | 12.1 |
| | H₂O₂ Solution | | Hardness | 30.2 | 31.0 | 30.9 | 30.8 |
| | | 70° C. | YI | 10.5 | 11.2 | 11.9 | 12.8 |
| | | | Hardness | 30.2 | 30.7 | 30.2 | 30.5 |
| Comparative | DIW | 25° C. | YI | 8.5 | 8.4 | 8.2 | 8.7 |
| Example 2 | | | Hardness | 31.2 | 31.5 | 31.8 | 31.5 |
| | | 70° C. | YI | 8.5 | 8.2 | 8.3 | 8.7 |
| | | | Hardness | 31.2 | 31.6 | 31.0 | 31.7 |
| | 3% by weight of | 25° C. | YI | 8.5 | 8.8 | 8.9 | 9.3 |
| | H₂O₂ Solution | | Hardness | 31.2 | 31.0 | 30.9 | 30.8 |
| | | 70° C. | YI | 8.5 | 8.8 | 8.6 | 9.4 |
| | | | Hardness | 31.2 | 31.8 | 31.9 | 31.5 |

Table 2 shows differences in the yellow index (YI) and the hardness for the polishing pad of each of Example 1, Example 2, Comparative Example 1 and Comparative Example 2 depending on the difference in the supply solution and the difference in the temperature.

According to the experimental results, it was identified that, when supplying DIW, the polishing pad of Example 1 had no significant difference in the hardness (Shore D) with values of 56.2, 57.1, 56.8 and 56.3 at 25° C., 56, 55.9 and 57.1 at 50° C., and 56.2, 56.7, 55.9 and 56.2 at 70° C. even after time passed.

In Example 2, it was also identified that, when supplying DIW, hardness (Shore D) measured over time was not significantly different with values of 56.2, 55.8, 56.2 and 55.7 at 25° C., 56.2, 55.0, 55.2 and 55.1 at 50° C., and 56.2, 54.8, 55.0 and 54.6 at 70° C.

Comparative Example 1 is also a case in which DIW was supplied, and it was identified that hardness (Shore D) measured over time was not significantly different with values of 31.2, 30.2, 30.8 and 30.5 at 25° C., and 31.2, 30.6, 30.0 and 30.7 at 70° C.

Comparative Example 2 is also a case in which DIW was supplied, and it was identified that hardness (Shore D) measured over time was not significantly different with values of 31.2, 31.5, 31.8 and 31.5 at 25° C., and 31.2, 31.6, 31.0 and 31.7 at 70° C.

In the case of the yellow index, Example 1 and Example 2 in which DIW was supplied had a yellow index of about 14, and the polishing pads of Comparative Example 1 and Comparative Example 2 had a yellow index of about 8, and it was identified that there were no temperature-dependent changes.

On the other hand, it was identified that, in the polishing pads of Example 1 and Example 2, the YI value increased over time when 3% by weight of a H₂O₂ solution was supplied, and when the temperature increased, the YI value increased.

Specifically, it was identified that the polishing pad of Example 1 had YI values of 14.8, 19.6, 20.1 and 15.5 at 25° C., YI values of 26.5, 27.7 and 33.8 at 50° C., and YI values of 14.8, 28.7, 33.8 and 33.8 at 70° C., indicating an increase as the treatment time passed.

In addition, it was identified that the polishing pad of Example 2 had YI values of 14.9, 18.2, 19.7 and 20.3 at 25° C., YI values of 14.9, 22.5, 23.7 and 28.8 at 50° C., and YI values of 14.9, 26.4, 29.3 and 30.2 at 70° C., indicating an increase as the treatment time passed.

On the other hand, in the polishing pad of Comparative Example 1, it was identified that the YI value was from 10.5 to 12.1 under a condition of 25° C., showing no significant change over time even when 3% by weight of a H₂O₂ solution was supplied, and the YI value did not significantly change either with values from 10.5 to 12.8 under a condition of 70° C.

In addition, in Comparative Example 2, it was identified that the YI value was from 8.5 to 9.3 under a condition of 25° C., showing no significant change over time, and the YI value did not significantly change either with values from 8.5 to 9.4 under a condition of 70° C.

The following Tables 3 and 4 show results of analyzing the experimental results of Table 2, and for Example in which changes in YI were observed, changes in the peaks before and after the experiment were identified in the FT-IR spectrum. Particularly, using the same method as in FIG. 6, the area at 1636 cm⁻¹ appearing as a characteristic IR peak was identified.

TABLE 3

| | | Temperature | | |
|---|---|---|---|---|
| | | (° C.)/ | | |
| Example 1 | Solution | Time (h) | Item | Result |
| Untreated | | | YI | 14.8 |
| | | | Hardness | 56.2 |
| | | | Characteristic IR | −0.17 |
| | | | Peak (1636 cm⁻¹) Area | |
| Treatment 1 | DIW | 25° C./90 | YI | 14.6 |
| | | | Hardness | 56.3 |
| | | | Characteristic IR | −0.14 |
| | | | Peak (1636 cm⁻¹) Area | |
| Treatment 2 | | 70° C./90 | YI | 14.7 |
| | | | Hardness | 56.2 |
| | | | Characteristic IR | −0.06 |
| | | | Peak (1636 cm⁻¹) Area | |
| Treatment 3 | 3% by | 25° C./90 | YI | 15.5 |
| | weight of | | Hardness | 55.5 |
| | H₂O₂ | | Characteristic IR | −0.06 |
| | Solution | | Peak (1636 cm⁻¹) Area | |
| Treatment 4 | | 70° C./90 | YI | 33.8 |
| | | | Hardness | 55.7 |
| | | | Characteristic IR | 0.13 |
| | | | Peak (1636 cm⁻¹) Area | |

TABLE 4

| | | Temperature | | |
|---|---|---|---|---|
| Comparative | | (° C.)/ | | |
| Example 1 | Solution | Time (h) | Item | Result |
| Untreated | | | YI | |
| | | | Hardness | |
| | | | Characteristic IR | −0.18 |
| | | | Peak (1636 cm⁻¹) Area | |
| Treatment 1 | DIW | 25° C./90 | YI | |
| | | | Hardness | |
| | | | Characteristic IR | −0.17 |
| | | | Peak (1636 cm⁻¹) Area | |
| Treatment 2 | | 70° C./90 | YI | |
| | | | Hardness | |
| | | | Characteristic IR | −0.10 |
| | | | Peak (1636 cm⁻¹) Area | |
| Treatment 3 | 3% by | 25° C./90 | YI | |
| | weight of | | Hardness | |
| | H₂O₂ | | Characteristic IR | −0.08 |
| | Solution | | Peak (1636 cm⁻¹) Area | |
| Treatment 4 | | 70° C./90 | YI | |
| | | | Hardness | |
| | | | Characteristic IR | 0.09 |
| | | | Peak (1636 cm⁻¹) Area | |

With the results of Table 2, YI and hardness values after 90 hours were identified for each of Example 1 (Table 3) and Comparative Example 1 (Table 4).

In addition, the point where a change in the IR spectrum appears before and after supplying 3% by weight of a H₂O₂ solution was identified. The point of change was identified to be 1636 cm⁻¹, and the area for the corresponding part was analyzed. The analysis results are shown in Table 3, and on the 1636 cm⁻¹ peak of a portion related to the change in Yellow Index (YI), a change occurred before and after being treated with 3% by weight of a H₂O₂ solution for 90 hours at 70° C., and the change in the peak was numerically identified through the analysis on the area for the degree of change.

### Experimental Example 2

In order to identify changes in the physical properties depending on the color change in the polishing layer, initial tensile and elongation were measured, and tensile strength, elongation and a change in the surface of the specimen after being treated as in the above-described Experimental Example were measured.

The maximum strength value immediately before breakage was obtained while performing the test at a rate of 500 mm/minute using a universal testing machine (UTM), and then through the obtained value, the tensile value was derived by calculating a slope in the 20% to 70% region of the Strain-Stress curve.

The maximum strain immediately before breakage was obtained while performing the test at a rate of 500 mm/minute using a universal testing machine (UTM), and then the elongation value was derived as a percentage (%) by the ratio of the maximum strain with respect to the initial length.

The treatment conditions for the polishing pad are Treatments 1 to 4 of Tables 3 and 4.

TABLE 5

| Example 1 | Elongation | Tensile Strength (N/m²) |
|---|---|---|
| Untreated | 101 | 18.75 |
| Treatment 1 | 108 | 19.01 |
| Treatment 2 | 99 | 18.62 |
| Treatment 3 | 104 | 17.84 |
| Treatment 4 | 107 | 18.03 |

TABLE 6

| Example 2 | Elongation | Tensile Strength (N/m²) |
|---|---|---|
| Untreated | 92 | 17.55 |
| Treatment 1 | 97 | 18.1 |
| Treatment 2 | 91 | 18.12 |
| Treatment 3 | 89 | 17.91 |
| Treatment 4 | 90 | 17.33 |

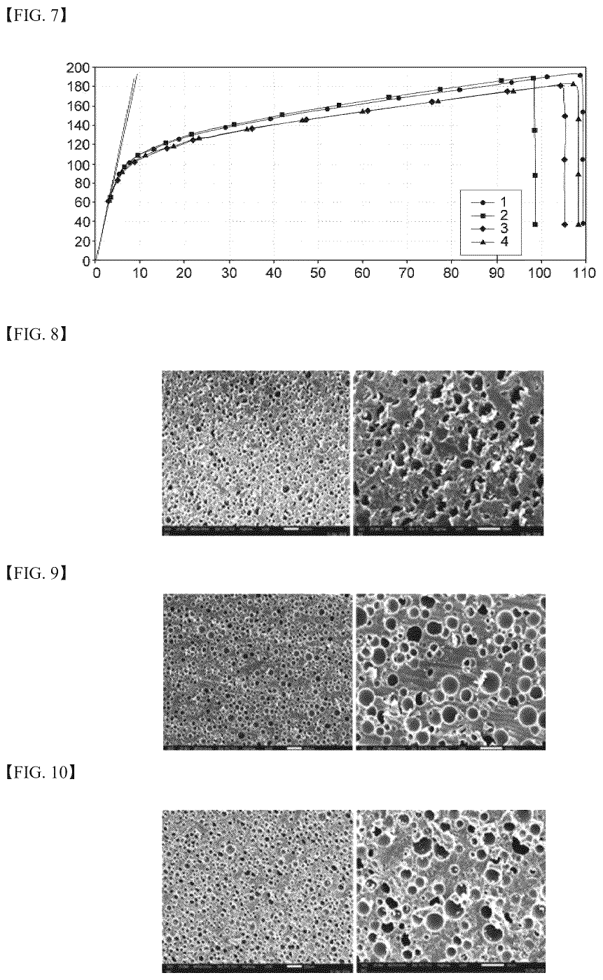

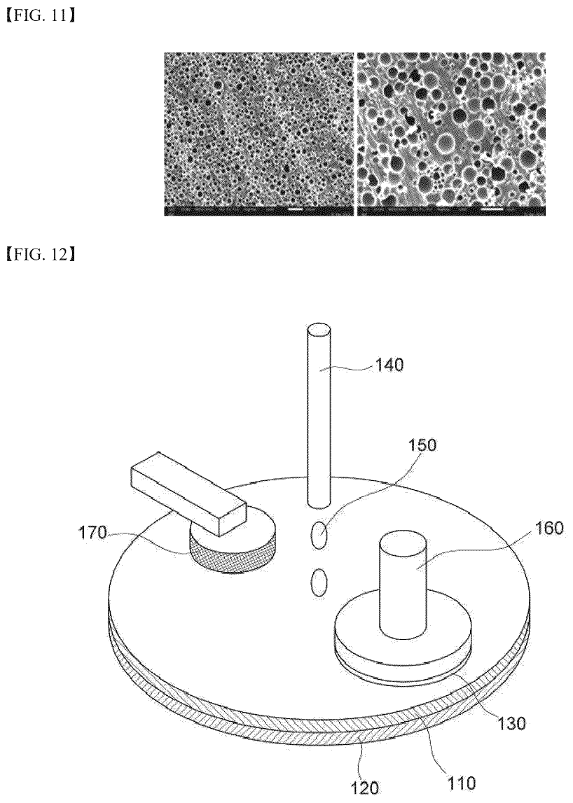

Tables 5, 6 and FIG. 7 show results of measuring changes in the physical properties depending on the treatment conditions of Tables 3 and 4. Specifically, FIG. 7 shows results of measuring tensile strength, and it was identified that there was no significant difference in the tensile strength compared to the untreated polishing pad.

In the polishing pad of Example 2, it was also identified that there was no significant difference in the tensile strength in the cases of Treatments 1 to 4 compared to the untreated case.

In the case of elongation, it was identified that the polishing pad of Example 1 showed similar elongation values of 108% in Treatment 1, 99% in Treatment 2, 104% in Treatment 3 and 107% in Treatment 4, identifying that there were no changes in the elongation and the tensile strength under the above-mentioned treatment conditions.

In addition, it was identified that the polishing pad of Comparative Example 2 showed similar elongation values of 92% in Treatment 1, 97% in Treatment 2, 89% in Treatment 3 and 90% in Treatment 4.

In addition, in the surface measurement results, FIG. 8 shows the untreated polishing pad (Treatment Condition 1), FIG. 9 shows the polishing pad treated with 3% by weight of a H₂O₂ solution for 90 hours under a 25° C. condition, FIG. 10 shows the polishing pad treated with 3% by weight of a H₂O₂ solution for 90 hours at 50° C., and FIG. 11 shows the polishing pad treated with 3% by weight of a H₂O₂ solution for 90 hours at 70° C. The left SEM and the right SEM of each of FIGS. 8 to 11 have magnifications adjusted to X100 and X300, respectively, and it may be identified that there is no temperature-dependent difference.

### Experimental Example 3

The polishing pads of Examples were treated under the same conditions as in Treatments 1 to 4 of Tables 3 and 4, and surface zeta potential was measured using ZETASIZER Nano-ZS90 (Malvern Panalytical), a zeta potential measuring device.

The zeta potential measuring device is a dip cell type, with an electrode at the end of the barrel (having the specimen attached therebetween), and includes an avalanche photo-iodide detection system.

Specifically, Each of the polishing pad samples (4 mm×5 mm, 20 mm²) obtained in Examples and Comparative Examples was attached to a sample holder 310 using a double-sided tape, 2 ml of a polishing slurry diluted to the dilution concentration described in the table below was introduced to a cuvette 330, and electrophoretic mobility was measured using an Ag/AgCl reversible electrode 320. The measured electrophoretic mobility changes as a function of a distance from the sample surface.

Using the following Equation 1, the surface zeta potential variance (Δ|Surface Zeta|Δ|Surface Zeta|) was calculated:

$$Δ \vert Surface Zeta \vert = \frac{( - {Intercept}_{i} + Tracer )}{( - {Intercept}_{a} + Tracer )} \qquad [ Equation 1 ]$$

herein,
Interceptᵢ is zeta potential of the polishing layer untreated with 3% by weight of an aqueous H₂O₂ solution,
Interceptₐ is zeta potential of the polishing layer after being treated with 3% by weight of an aqueous H₂O₂ solution, and
Tracer is zeta potential of a silica slurry.

In Equation 1, Interceptᵢ and Interceptₐ are obtained from extrapolation after measuring the diffusion layer 120 of ions in FIG. 14.

TABLE 7

| | |
|---|---|
| Slurry Type | Silica Slurry (LSS Slurry) |
| Composition Ratio | Fumed Silica Particles: 12% by Weight |
| | pH Regulator (KOH): 0.2% |
| | Residual Amount of Deionized Water |
| Solid Content (% by weight) | 12 |
| pH | 10.5 |
| Zeta Potential of Slurry (mV) | −35 mV to −45 mV |
| Average Particle Diameter (nm) | 150 nm |
| Dilution Concentration | 12% → 0.5% sol. |

Results of measuring zeta potential under the experimental condition of Table 7 are shown in the following Tables 8 and 9.

TABLE 8

| | Intercept | Tracer | Surface | Equation |
|---|---|---|---|---|
| Example 1 | (mV) | (mV): LSS | Zeta (mV) | 1 |
| Untreated | 19.0 | −41.9 | −60.9 | — |
| Treatment 1 | 18.9 | −39.3 | −58.2 | 1.005 |
| Treatment 2 | 19.2 | −41.3 | −60.5 | 0.990 |
| Treatment 3 | 19.5 | −40.9 | −60.4 | 0.974 |
| Treatment 4 | 32.9 | −35.7 | −68.7 | 0.576 |

TABLE 9

| | Intercept | Tracer | Surface | Equation |
|---|---|---|---|---|
| Example 2 | (mV) | (mV): LSS | Zeta (mV) | 1 |
| Untreated | 18.5 | −40.3 | −61.2 | — |
| Treatment 1 | 19.3 | −38.9 | −58.8 | 1.050 |
| Treatment 2 | 19.6 | −41.0 | −60.9 | 1.050 |
| Treatment 3 | 19.8 | −41.4 | −60.6 | 1.089 |
| Treatment 4 | 33.2 | −35.1 | −68.2 | 0.631 |

When using the pad of the present disclosure, the polishing pad under the condition of Treatment 4 (immersion for 90 hours at 70° C. under 3% by weight of H₂O₂ solution environment) had surface zeta potential of −68.7 mV, indicating that the surface zeta potential increased to a negative value compared the untreated polishing pad.

On the other hand, the polishing pad under the condition of Treatment 1 had surface zeta potential of −58.2 mV, the polishing pad under the condition of Treatment 2 had surface zeta potential of −60.5 mV, and the polishing pad under the condition of Treatment 3 had surface zeta potential of −60.4 mV, identifying that the zeta potential values were lower compared to the polishing pad under the untreated condition.

As for the results of calculating the values of Equation 1, it was identified that the polishing pad of Example 1 had a value of 0.576 under the condition of Treatment 4, 1.005 under the condition of Treatment 1, 0.990 under the condition of Treatment 2, and 0.974 under the condition of Treatment 3, which were different from that of the polishing pad under the condition of Treatment 4.

In addition, it was identified that the polishing pad of Example 2 had a value of 0.631 under the condition of Treatment 4, 1.050 under the condition of Treatment 1, 1.050 under the condition of Treatment 2, and 1.089 under the condition of Treatment 3, which were different from that of the polishing pad under the condition of Treatment 4.

When the surface zeta potential of the polishing pad increases to a negative value and the value by Equation 1 is 0.9 or less as described above, repulsive force with a semiconductor wafer having negative zeta potential increases, and the occurrence of defects may be reduced when used in a polishing process.

### Experimental Example 4

### <Polishing Rate for Tungsten (W) Film>

A silicon wafer having a diameter of 300 mm on which a tungsten (W) film was formed by a CVD process was installed using a CMP polishing device. After that, on a surface plate to which the polishing pad was attached, the silicon wafer was set so that the tungsten film was downside. After that, the polishing load was adjusted to 2.8 psi, and the tungsten film was polished by rotating the surface plate at 115 rpm for 30 seconds while introducing a colloidal silica slurry onto the polishing pad at a rate of 190 ml/minute. After the polishing, the silicon wafer was removed from the carrier, installed on a spin dryer, washed with deionized water (DIW), and then dried with air for 15 seconds. For the dried silicon wafer, a difference in the thickness before and after the polishing was measured using a contact-type surface resistance measuring device (4-point probe). After that, the polishing rate was calculated using the following Mathematical Equation 1.

Polishing Rate (Å/minute)=Difference in thickness before and after polishing (Å)/Polishing time (minute) <Mathematical Equation 1>

### <Polishing Rate for Oxide (O) Film>

In addition, using the same device, a silicon wafer having a diameter of 300 mm on which a silicon oxide (SiOx) film is formed by a TEOS-plasma CVD process was installed instead of the tungsten film-formed silicon wafer. After that, on a surface plate to which the polishing pad was attached, the silicon wafer was set so that the silicon oxide film was downside. After that, the polishing load was adjusted to 1.4 psi, and the silicon oxide film was polished by rotating the surface plate at 115 rpm for 60 seconds while introducing a fumed silica slurry onto the polishing pad at a rate of 190 ml/minute. After the polishing, the silicon wafer was removed from the carrier, installed on a spin dryer, washed with deionized water (DIW), and then dried with air for 15 seconds. For the dried silicon wafer, a difference in the thickness before and after the polishing was measured using an optical interference thickness measuring device (manufacturer: Keyence Corporation, model name: SI-F80R). After that, the polishing rate was calculated using Mathematical Equation 1.

### <Measurement of the Number of Surface Defects Such as Scratches and Chatter Marks>

After performing the CMP process by the procedure as above using each of the polishing pads of Examples and Comparative Examples, the number of surface defects such as scratches and chatter marks appearing on the wafer surface after the polishing was measured using a defect inspection device (AIT XP+, KLA Tencor Corporation) (condition: threshold 150, die filter threshold 280).

The scratches refer to substantially continuous linear scratch marks, and, for example, mean defects having a shape as shown in FIG. 15.

Meanwhile, the chatter marks refer to substantially discontinuous linear scratch marks, and, for example, mean defects having a shape as shown in FIG. 16.

TABLE 10

| Slurry Type | Fumed Silica | Colloidal Silica |
|---|---|---|
| | Slurry (Slurry 1) | Slurry (Slurry 2) |
| Composition Ratio | Fumed Silica | Colloidal Silica: |
| | Particles: 12% by Weight | 3% by Weight |
| | pH Regulator (KOH): 0.2% | Amino Acid: 0.1% |
| | | Organic Acid: 0.05% |
| | | Sugar Alcohols: 1% |
| | Residual Amount of Deionized Water | |
| Solid Content | 12 | 4 |
| (% by weight) | | |
| pH | 10.5 | 4.0 |
| Average Particle | 150 nm | 40 nm |
| Diameter (nm) | | |

The polishing rate and the defects after the polishing process were identified under the above-mentioned experimental condition, and the results are identified through the following Table 11.

TABLE 11

| | | | Example 1 | | Example 2 | |
|---|---|---|---|---|---|---|
| | | | Polishing Pad | Polishing Pad | Polishing Pad | Polishing Pad |
| | Wafer | | under 20° C. | under 70° C. | under 20° C. | under 70° C. |
| | Film | Slurry | Condition | Condition | Condition | Condition |
| Polishing | Oxide | Slurry 1 + DIW | 3795 | 3914 | 3825 | 3885 |
| Rate (Å/min) | | | | | | |
| | | Slurry 1 + 3% by | 3801 | 3945 | 3776 | 3872 |
| | | weight of H₂O₂ | | | | |
| | | Solution | | | | |
| Scratches | | Slurry 1 + DIW | 12 | 5 | 10 | 5 |
| and Chatter | | Slurry 1 + 3% by | 7 | 2 | 8 | 3 |
| Marks (Number) | | weight of H₂O₂ | | | | |
| | | Solution | | | | |
| Polishing | Tungsten | Slurry 2 + DIW | 1885 | 1970 | 1876 | 1933 |
| Rate (Å/min) | | Slurry 2 + 3% by | 1874 | 1981 | 1855 | 1947 |
| | | weight of H₂O₂ | | | | |
| | | Solution | | | | |
| Scratches | | Slurry 2 + DIW | 10 | 3 | 11 | 2 |
| and Chatter | | Slurry 2 + 3% by | 5 | 0 | 7 | 2 |
| Marks (Number) | | weight of H₂O₂ | | | | |
| | | Solution | | | | |

The results of measuring the polishing rate and the occurrence of defects after the polishing process are shown in Table 9. According to Table 7, it may be identified that the results of measuring the polishing rates under the condition of, while providing the same slurry, supplying DIW and under the condition of supplying 3% by weight of H₂O₂ showed no significant difference in the polishing rates.

However, as for the occurrence of defects such as scratches and chatter marks, it may be identified that the defects occur less under the condition of supplying 3% by weight of H₂O₂ compared to the case of supplying DIW. This indicates that the surface zeta potential of the polishing pad showed a larger negative value under the condition of supplying 3% by weight of H₂O₂, and the occurrence of defects may be prevented due to stronger repulsive force with a semiconductor wafer showing negative zeta potential on the surface.

In addition, the difference in the polishing rate depending on the temperature condition is due to the difference in the friction between a head pressure, a conditioner pressure and the like in the polishing process, and it was identified that a relatively higher level of polishing rate was obtained when the polishing process was performed using the polishing pad under a 70° C. condition compared to the case in which the polishing process was performed under a 20° C. condition.

Hereinbefore, preferred embodiments of the present disclosure have been described in detail, however, the scope of a right of the present disclosure is not limited thereto, and various modified and improved forms made by those skilled in the art using the basic concept of the present disclosure defined in the attached claims also fall within the scope of a right of the present disclosure.

### REFERENCE NUMERAL

1: Tensile strain of untreated polishing pad
2: Tensile strain of polishing pad treated with 3% by weight of aqueous H₂O₂ solution for 90 hours at 25° C.
3: Tensile strain of polishing pad treated with 3% by weight of aqueous H₂O₂ solution for 90 hours at 50° C.
4: Tensile strain of polishing pad treated with 3% by weight of aqueous H₂O₂ solution for 90 hours at 70° C.
10: Polishing layer
20: Adhesive layer
30: Cushion layer
110: Polishing pad
120: Surface plate
130: Semiconductor substrate
140: Nozzle
150: Polishing slurry
160: Polishing head
170: Conditioner
200: Polishing pad
210: Fixed layer
220: Diffusion layer of ions
230: Slipping plane
310: Sample holder
320: Electrode
330: Cuvette

1. A polishing pad comprising a polishing layer,
wherein the polishing layer is treated with 3% by weight of an aqueous H₂O₂ solution for 90 hours at 70° C., and the polishing layer treated with 3% by weight of the aqueous H₂O₂ solution has a peak appearing at 1620 cm⁻¹ to 1650 cm⁻¹ when measuring an FT-IR (Fourier Transform Infrared Spectroscopy) spectrum.

2. The polishing pad of claim 1, wherein the polishing layer is treated with 3% by weight of an aqueous H₂O₂ solution for 90 hours at 70° C., and the polishing layer treated with 3% by weight of the aqueous H₂O₂ solution has a peak appearing at 1636 cm⁻¹ when measuring an FT-IR (Fourier Transform Infrared Spectroscopy) spectrum.

3. The polishing pad of claim 2, wherein the polishing layer is treated with 3% by weight of an aqueous H₂O₂ solution for 90 hours at 70° C., and the polishing layer treated with 3% by weight of the aqueous H₂O₂ solution has a peak area of 0.10 to 0.20 at 1636 cm⁻¹ when measuring an FT-IR (Fourier Transform Infrared Spectroscopy) spectrum.

4. The polishing pad of claim 1, wherein the polishing layer is treated with 3% by weight of an aqueous H₂O₂ solution for 30 hours to 90 hours at 70° C., and the polishing layer treated with 3% by weight of the aqueous H₂O₂ solution has a yellow index of 10 to 50.

5. The polishing pad of claim 1, wherein the polishing layer treated with 3% by weight of H₂O₂ has a yellow index (YI) of 10 to 35 after 30 hours in a state of pH 6.

6. The polishing pad of claim 1, wherein the polishing layer treated with 3% by weight of H₂O₂ has a yellow index (YI) of 20 to 50 after 60 hours in a state of pH 6.

7. The polishing pad of claim 1, wherein the polishing layer treated with 3% by weight of H₂O₂ has a yellow index (YI) of 20 to 50 after 90 hours in a state of pH 6.

8. The polishing pad of claim 1, wherein the polishing layer is treated with 3% by weight of an aqueous H₂O₂ solution for 90 hours at 70° C., and, after introducing a silica slurry of −35 mV to −45 mV, surface zeta potential that is a sum of zeta potential (Intercept) of the polishing layer and zeta potential (Tracer) of the silica slurry is from −50 mV to −80 mV.

9. The polishing pad of claim 1, wherein the polishing layer has an elongation of 60% to 140%.

10. The polishing pad of claim 1, wherein the polishing layer has tensile strength of 15 N/m² to 20 N/m².

11. The polishing pad of claim 1, wherein the polishing layer has surface hardness of 55 shore D to 65 shore D.

12. The polishing pad of claim 1, wherein the polishing layer has a plurality of pores formed therein, and the pores have a diameter of 10 μm to 30 μm.

13. A method for manufacturing a semiconductor device, the method comprising:
providing a polishing pad including a polishing layer; and
polishing a semiconductor substrate while conducting relative rotation so that a surface to be polished of the semiconductor substrate is in contact with a polishing surface of the polishing layer,
wherein the polishing layer is treated with 3% by weight of an aqueous H₂O₂ solution for 90 hours at 70° C., and the polishing layer treated with 3% by weight of the aqueous H₂O₂ solution has a peak appearing at 1620 cm⁻¹ to 1650 cm⁻¹ when measuring an FT-IR (Fourier Transform Infrared Spectroscopy) spectrum.

14. The method of claim 13, wherein the polishing layer is treated with 3% by weight of an aqueous H₂O₂ solution for 90 hours at 70° C., and the polishing layer treated with 3% by weight of the aqueous H₂O₂ solution has a peak appearing at 1636 cm⁻¹ when measuring an FT-IR (Fourier Transform Infrared Spectroscopy) spectrum.

15. The method of claim 13, wherein the polishing layer is treated with 3% by weight of an aqueous H₂O₂ solution for 30 hours to 90 hours at 70° C., and the polishing layer treated with 3% by weight of the aqueous H₂O₂ solution has a yellow index of 10 to 50.

16. The method of claim 13, wherein the polishing layer is treated with 3% by weight of an aqueous H₂O₂ solution for 90 hours at 70° C., and, after introducing a silica slurry of −35 mV to −45 mV, surface zeta potential that is a sum of zeta potential (Intercept) of the polishing layer and zeta potential (Tracer) of the silica slurry is from −50 mV to −80 mV.

17. The method of claim 13, wherein the polishing layer has an elongation of 60% to 140%.

18. The method of claim 13, wherein the polishing layer has tensile strength of 15 N/m² to 20 N/m².

19. The method of claim 13, wherein the polishing layer has a plurality of pores formed therein, and the pores have a diameter of 10 μm to 30 μm.

20. A polishing pad comprising a polishing layer,
wherein the polishing layer has a surface zeta potential variance (Δ|Surface Zeta|Δ|Surface Zeta|) according to the following Equation 1 of 0.1 to 10:
$$Δ \vert Surface Zeta \vert = \frac{( - {Intercept}_{i} + Tracer )}{( - {Intercept}_{a} + Tracer )} \qquad [ Equation 1 ]$$
herein,
Interceptᵢ is zeta potential of the polishing layer untreated with 3% by weight of an aqueous H₂O₂ solution;
Interceptₐ is zeta potential of the polishing layer after being treated with 3% by weight of an aqueous H₂O₂ solution; and
Tracer is zeta potential of a silica slurry.
